(19) United States
(12) Patent Application Publication
(10) Pub. No.: US 2014/0210567 A1
(43) Pub. Date: Jul. 31, 2014

(54) CRYSTAL RESONATOR, CRYSTAL RESONATOR PACKAGE, AND OSCILLATOR

(71) Applicant: NIHON DEMPA KOGYO CO., LTD., TOKYO (JP)

(72) Inventor: MITSUAKI KOYAMA, SAITAMA (JP)

(73) Assignee: NIHON DEMPA KOGYO CO., LTD., TOKYO (JP)

(21) Appl. No.: 14/156,430

(22) Filed: Jan. 15, 2014

(30) Foreign Application Priority Data
Jan. 29, 2013 (JP) 2013-013846

(51) Int. Cl. H03B 5/30

(52) U.S. Cl. CPC H03B 5/30
USPC 331/158

(57) ABSTRACT

A crystal resonator includes a plate-shaped crystal element, excitation electrodes, and a second crystal region. The plate-shaped crystal element is supported to a supporting portion. The crystal element is configured to vibrate at a thickness shear vibration. The excitation electrodes are disposed at both surfaces of a first crystal region of the crystal element. The second crystal region is positioned outside with respect to the excitation electrodes. The second crystal region is formed at a peripheral edge portion of the crystal element so as to occupy a region of equal to or more than 75% of a whole circumference of the crystal element. The second crystal region has a positive/negative direction of an X-axis of a crystal different from a positive/negative direction of an X-axis of a crystal of the first crystal region.

### CROSS-REFERENCE TO RELATED APPLICATION

This application claims the priority benefit of Japanese application serial no. 2013-013846, filed on Jan. 29, 2013. The entirety of the above-mentioned patent application is hereby incorporated by reference herein and made a part of specification.

### BACKGROUND

1. Technical Field

The present disclosure relates to a crystal resonator for outputting an oscillation frequency, a crystal resonator package, and an oscillator.

2. Description of the Related Art

Crystal resonators are used in various fields such as electronic equipment, measuring instruments, and communication devices, and especially an AT-cut crystal resonator whose main vibration is thickness shear vibration is often used because of its good frequency characteristics, but it has a problem that unnecessary unwanted response is generated. Unnecessary unwanted response, if generated, is coupled to main vibration, which involves a concern about the occurrence of a frequency jump. When the main vibration is thickness shear vibration, other kinds of unwanted response such as face shear vibration can be unwanted response. These unwanted responses will be a cause of the generation of Activity dips and Frequency dips.

As a method for reducing the unwanted response, a method that finds a design specification of a crystal element where the unwanted response is less likely to occur mainly utilizing numerical simulation or an existing simulation software is available. However, with this method, processes of the crystal resonators significantly vary; and therefore it is difficult to sufficiently reduce the unwanted response in all crystal resonators. Accordingly, to stably supply the crystal resonators where generation of the unwanted response is sufficiently reduced, elaborated design and tests are required, arising a problem of taking long time. Additionally, in accordance with downsizing of the crystal resonator, more elaborated design is required.

Japanese Unexamined Patent Application Publication No. 2000-36724 (paragraph 0047) discloses a technique that prevents a mass of an adhesive agent, for example, from affecting a vibrating region by forming twins at parts connected to supporting portions of the crystal resonator. However, this does not solve the problem of the present disclosure.

The present disclosure has been made in view of the circumstances, and an aim thereof is to provide a technique that minimizes Activity dips generated at oscillated high frequency by a simple method when a crystal resonator supported to a supporting portion that performs thickness shear vibration is oscillated.

### SUMMARY

A crystal resonator of the present disclosure is a crystal resonator that is supported to a supporting portion and is configured to vibrate at a thickness shear vibration. The crystal resonator includes a plate-shaped crystal element, excitation electrodes, and a second crystal region. The excitation electrodes are disposed at both surfaces of a first crystal region of the crystal element. The second crystal region is formed along a region of equal to or more than 75% of a whole circumference of the crystal element when viewed from a flat plate surface of the crystal element. The second region has a positive/negative direction of an X-axis of a crystal different from a positive/negative direction of an X-axis of a crystal of the first crystal region. That is, a positive/negative direction of an X-axis of a crystal in the second crystal region is reverse to a positive/negative direction of an X-axis of a crystal in the first crystal region.

The crystal element has a rectangular shape. The second crystal region may be formed at least at a region of the peripheral edge portion along remaining sides excluding one side of the crystal element. The crystal element may be secured to a supporting portion at positions of both ends of one side where a second crystal region is not formed. The crystal element is cut out at an AT-cut. The first crystal region may be an AT-cut region where a positive/negative direction of an X-axis remains in cutout of the crystal element. The crystal element may have a (maximum length lengthwise of the crystal element/thickness of the crystal element) value of equal to or less than 100. The crystal element may have a rectangular shape. The second crystal region may be formed in a strip shape. Assuming that a separation distance between sides of the crystal elements opposed to one another is “d”, a width of the second crystal region may be 0.1d to 0.2d. The crystal element has a circular shape. The second crystal region is formed in a strip shape. Assuming that a diameter of the crystal element is “r”, a width of the second crystal region is 0.1r to 0.2r.

A crystal resonator package of the present disclosure includes the above-described crystal resonator, a container, and an electrode portion. The container includes the supporting portion. The electrode portion is disposed in the container. The electrode portion is configured to conduct the excitation electrode and an external part.

An oscillator of the present disclosure includes the above-described crystal resonator package and an oscillator circuit. The oscillator circuit is connected to the electrode portion. The oscillator circuit is configured to oscillate a crystal resonator.

The plate-shaped crystal resonator is supported to the supporting portion. The crystal resonator vibrates at a thickness shear vibration. Twins are formed in the crystal resonator. The twins include an axis inverted region. The axis inverted region is positioned outside with respect to the excitation electrodes of the crystal resonator. The axis inverted region is formed at the region across the peripheral edge of the crystal element. The part of the peripheral edge portion of the crystal resonator is free end for face shear vibration, which is generated as an unwanted response against the main vibration, which is thickness shear vibration. Accordingly, forming the peripheral edge portion of the crystal resonator to have different characteristics reduces the unwanted response, which is the face shear vibration. Accordingly, when the crystal resonator is oscillated, Activity dips are less likely to occur in oscillated high frequency.

### BRIEF DESCRIPTION OF THE DRAWINGS

FIG. 1 is a perspective view illustrating a crystal resonator package.

FIG. 2 is a longitudinal cross-sectional side view illustrating the crystal resonator package.

FIG. 3A to FIG. 3C illustrate a crystal resonator according to an embodiment of the present disclosure, FIG. 3A is a plan view illustrating a top surface side, FIG. 3B is a plan view illustrating an inferior surface side, and FIG. 3C is a cross-sectional view.

FIG. 4A and FIG. 4B are explanatory drawings illustrating a face shear vibration of the crystal resonator.

FIG. 5 is an explanatory drawing illustrating an action of the crystal resonator according to this embodiment.

FIG. 6 is a plan view illustrating the crystal resonator according to another embodiment of the present disclosure.

FIG. 7 is a plan view illustrating the crystal resonator according to another embodiment of the present disclosure.

FIG. 8 is a characteristic view illustrating characteristics of the crystal resonator according to a working example.

FIG. 9 is a characteristic view illustrating characteristics of the crystal resonator according to the working example.

FIG. 10 is a characteristic view illustrating characteristics of the crystal resonator according to a comparative example.

### DETAILED DESCRIPTION

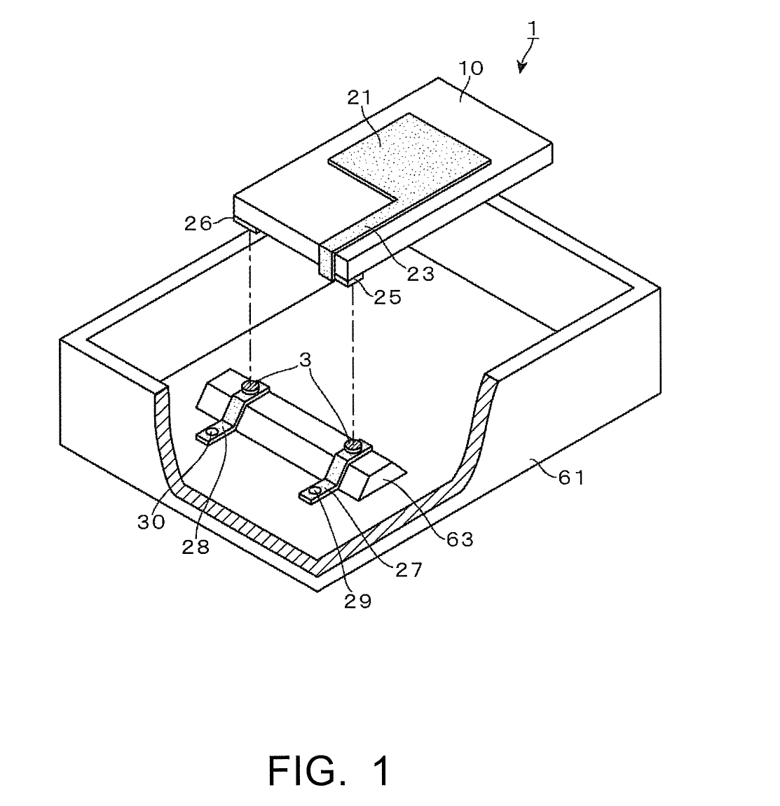

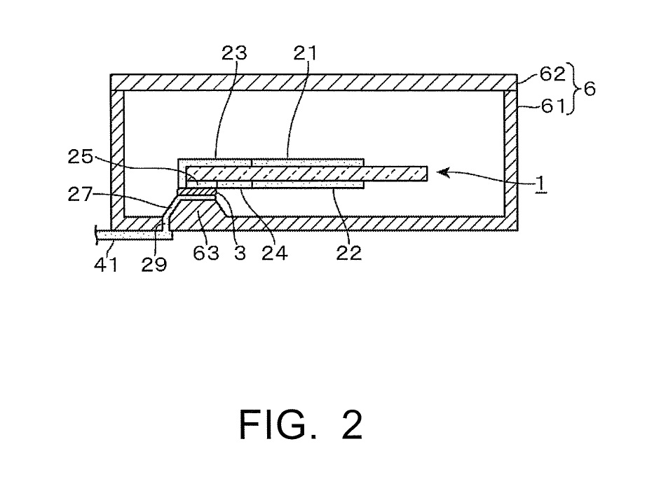

A description will be given of a crystal resonator package with a crystal resonator according to embodiments of the present disclosure. As illustrated in FIG. 1 and FIG. 2, the crystal resonator package includes a container 6, a crystal resonator 1, and a pedestal portion 63 that supports the crystal resonator 1. The container 6 is formed of a rectangular base body 61 and a rectangular lid portion 62 made of alumina, for example. The pedestal portion 63, which serves as a supporting portion for supporting the crystal resonator 1, is formed closer to one end lengthwise, and extends widthwise on the base body 61. The pedestal portion 63 includes connecting electrodes 27 and 28 arranged in an extension direction of the pedestal portion 63 on the top surface. The connecting electrodes 27 and 28 are connected to a conductive path 41 via an inclined surface of each pedestal portion 63, an inner bottom surface of the base body 61, and through-holes 29 and 30. The conductive path 41 is wired on an outer bottom surface of the base body 61. The through-holes 29 and 30 pass through a bottom wall of the base body 61.

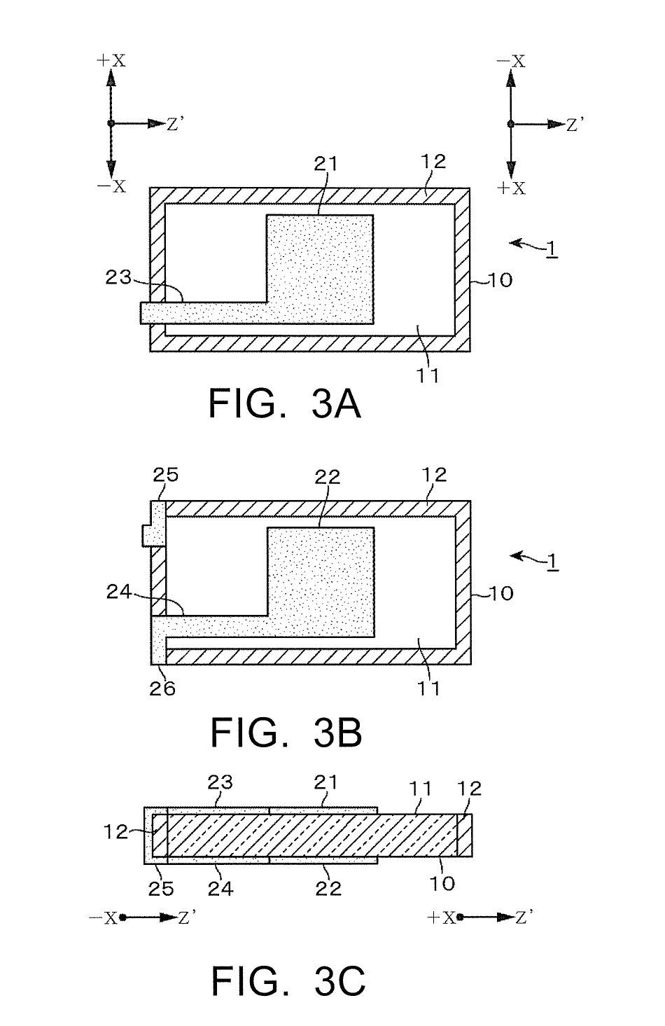

The crystal resonator 1 will be described with reference to FIG. 3A to FIG. 3C. FIG. 3A and FIG. 3B illustrate respective top surface side and inferior surface side of the crystal resonator 1. FIG. 3C illustrates a side cross-sectional view of the crystal resonator 1. As illustrated in FIG. 3A and FIG. 3B, a crystal element 10 has, for example, a rectangular shape with a short side of 2.5 mm and a long side of 5.0 mm.

The crystal element 10 is formed as a strip-shaped region where a peripheral edge portion of the AT-cut crystal element is formed of a β quartz crystal portion of 0.15 mm-width across the whole circumference. The β quartz crystal portion is a region where a crystallographic axis is inverted with respect to the AT-cut crystal region. That is, the crystal element 10 is formed as follows. The peripheral edge portion of the crystal element 10 is the β quartz crystal portion. A central region excluding the peripheral edge portion is an α quartz crystal portion, which is an AT-cut crystal region. More specifically, the first crystal region (hereinafter referred to as “α quartz crystal portion”) 11 on a center side of the crystal element 10 is formed parallel to a surface formed with Z′-axis, which is inclined approximately 35° counterclockwise with respect to a Z-axis viewed from the +direction of the X-axis extending in the width direction of the crystal element 10, and the X-axis. The Z-axis is a crystallographic axis with the front surface and the rear surface extending lengthwise of the crystal element 10. That is, the α quartz crystal portion 11 is AT-cut region. Meanwhile, a second crystal region forming the peripheral edge portion (hereinafter referred to as “β quartz crystal portion) 12 is formed such that the front surface and the rear surface are parallel to a surface formed with the Z′-axis and the X-axis. The positive/negative direction of the X-axis is configured to be inverse to the positive/negative direction of the X-axis of the α quartz crystal portion 11. That is, this crystal element 10 is configured as electrical twins. The β quartz crystal portion 12 is configured as about BT-cut region. The following describes the part of the crystal element 10 based on a rectangular shape viewed from a flat plate surface.

The crystal resonator package with the above-described crystal resonator can be mounted on a printed circuit board together with an oscillator circuit and a peripheral element and can be used as an oscillator.

A method for manufacturing the crystal resonator 1 will be described. The crystal resonator 1 is manufactured of the AT-cut rectangular crystal element 10, for example. The crystal element 10 is placed on square ring-shaped ceramic heater such that the region along the whole circumference of the peripheral edge portion contacts the ceramic heater and heated to 600° C., for example. At the center side region of the crystal element, a silicon plate is applied. The silicon plate serves as a heatsink to prevent the region from being heated by heat conduction. A crystal has a characteristic that causes phase transition at excess of 573° C. and inverts the crystallographic axis when cooled to equal to or less than 573° C. again. Therefore, in the crystal element 10, the region along the whole circumference of the peripheral edge portion causes phase transition, and the region becomes a BT-cut crystal region, for example. That is, the crystal element 10 forms twins. The twins include the AT-cut α quartz crystal portion 11 at a position closer to the center and the β quartz crystal portion 12, which is the BT-cut second crystal region, at the peripheral edge portion.

The crystal element 10 includes excitation electrodes 21 and 22, which vibrate the α quartz crystal portion 11, on both surfaces. The excitation electrodes 21 and 22 are opposed to one another at the α quartz crystal portion 11 parts in the crystal element 10. Accordingly, the β quartz crystal regions are disposed outside of the excitation electrodes so as to surround the excitation electrodes 21 and 22. The excitation electrodes 21 and 22 are formed in a rectangular, for example. Furthermore, one end of an extraction electrode 23 is connected to a part of the excitation electrode 21 on one side of the surface. The extraction electrode 23 is extracted toward inside of one short side of the crystal element 10, for example. One end of an extraction electrode 24 is connected to a part of the excitation electrode 22 on the other side of the surface. The extraction electrode 24 goes toward the same short side.

The extraction electrode 24 on the inferior surface side is extended to a peripheral edge of one short side on the inferior surface side of the crystal element 10. The extraction electrode 23 on the top surface side is extended to a side surface of one short side of the crystal element 10 and then is extended to the peripheral edge of one short side on the inferior surface side of the crystal element 10. Each extraction electrode 23 and 24 is extended to respective both ends of the crystal element 10 along one short side at the inferior surface of the crystal element 10, so as to form terminal portions 25 and 26. The excitation electrode 21 and the extraction electrode 23 on the one surface are integrally formed, and the excitation electrode 22 and the extraction electrode 24 on the other surface are integrally formed. These excitation electrodes 21 and 22 are formed of a laminated film of chromium (Cr) and gold (Au), for example.

The terminal portions 25 and 26 of the crystal resonator 1 are connected to respective connecting electrodes 27 and 28 disposed at the pedestal portion 63 using a conductive adhesive 3. The conductive adhesive 3 mutually conducts the terminal portions 25 and 26 and the connecting electrodes 27 and 28 and secures the crystal resonator 1 to the top surface of the pedestal portion 63. In view of this, the crystal resonator 1 is supported by one end at a horizontal posture. After the crystal resonator 1 is secured to the base body 61, the top surface of the base body 61 is closed with the lid portion 62, and the inside is vacuumed, for example, thus the crystal resonator package is formed.

An action of the crystal resonator 1 of the embodiment of the present disclosure will be described. In the case where the above-described crystal resonator package is connected to an oscillator circuit, such as a Colpitts circuit, and oscillated, for example, a high frequency due to thickness shear vibration is oscillated as a main vibration. Further, as a vibration other than the main vibration, a face shear vibration is generated as unwanted response, for example.

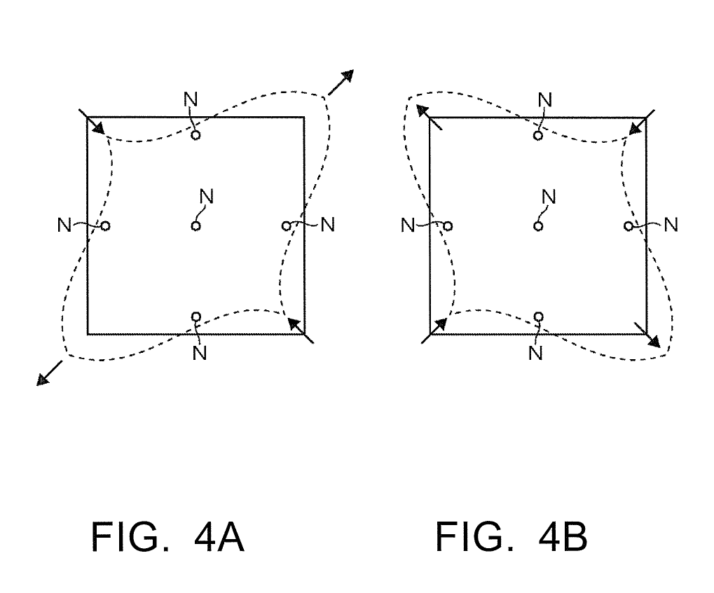

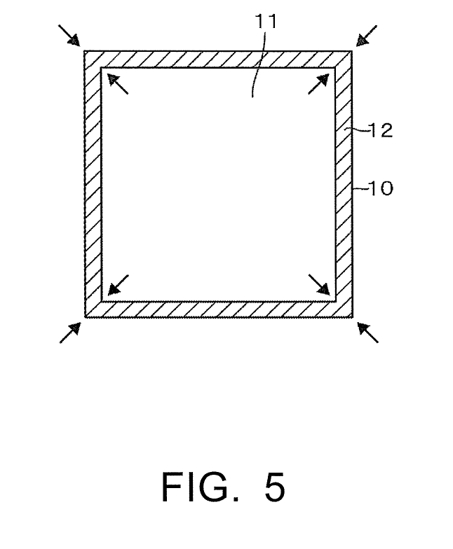

As illustrated by the dashed lines in FIG. 4A, the face shear vibration expands in one diagonal direction and contracts in the other diagonal direction in plan view, for example. After that, as illustrated by the dashed lines in FIG. 4B, the face shear vibration contracts in one diagonal direction and expands in the other diagonal direction, repeating this expansion and contraction operations. FIG. 4A and FIG. 4B and FIG. 5 illustrate examples where the expansion and contraction are repeated in the diagonal directions of the square crystal resonator 1. For the face shear vibration, nodes N (nodal points for vibration) are formed at positions dividing each of four sides into two at the center of the crystal resonator 1 and the peripheral edge portions of the crystal element 10. Positions of each apex of the crystal element 10 are free ends where displacement due to vibration becomes the largest.

The crystal resonator 1 of the embodiment of the present disclosure includes the β quartz crystal portion 12 along the whole circumference of the crystal element 10. Accordingly, since the peripheral edge portion of the crystal resonator 1 is secured by the β quartz crystal portion 12, the crystal resonator 1 is less likely to deform in the diagonal direction. Accordingly, in the case where a current is applied to the crystal resonator 1 with the β quartz crystal portion 12 at the peripheral edge portion and is oscillated at the thickness shear vibration, expansion and contraction forces are applied in the arrow direction illustrated in FIG. 5 by unwanted response. However, the β quartz crystal portion 12, which is disposed surrounding the crystal resonator 1, reduces deformation in the diagonal direction. Therefore, the face shear vibration expressed as an unwanted response is reduced.

According to the above-described embodiment, the plate-shaped crystal resonator 1 is supported to the supporting portion by one end or both ends. The crystal resonator 1 vibrates at a thickness shear vibration. Twins are formed in the crystal resonator 1. The twins include an axis inverted region that is positioned outside with respect to the excitation electrodes 21 and 22 of the crystal resonator 1. The axis inverted region is formed at the region across the peripheral edge of the crystal element 10. The part of the peripheral edge portion of the crystal resonator 1 is free end for face shear vibration (free vibrating region), which is generated as an unwanted response against the main vibration, which is thickness shear vibration. Accordingly, reducing the vibration at the peripheral edge portion reduces the face shear vibration. Accordingly, when the crystal resonator 1 is oscillated in the main vibration, generation of Activity dips due to unwanted response to the oscillation frequency is reduced.

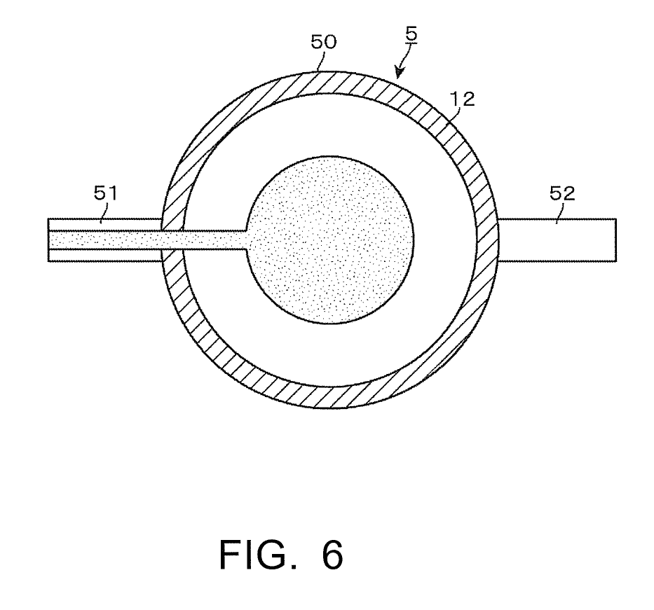

The crystal resonator of the present disclosure may be a circular plate-shaped crystal element 50. As illustrated in FIG. 6, the β quartz crystal portion 12, which is an axis inverted region, is formed along the peripheral edge portion of a circular plate-shaped crystal resonator 5. The crystal resonator is secured to the supporting portion with two supporting arms 51 and 52 and oscillates in the thickness shear vibration, for example.

In the circular plate-shaped crystal resonator 5, the nodal points for vibration are formed at positions where each supporting arm 51 and 52 extends at the center portion of the crystal resonator 5 and the peripheral edge portion of the crystal resonator 5, thus the face shear vibration, which is an unwanted response, is generated. However, the β quartz crystal portion 12 is disposed so as to surround the peripheral edge portion of the crystal resonator 5 for securing the crystal resonator 5. This reduces deformation of the crystal resonator 5 in the horizontal direction, reducing an unwanted response, which performs the face shear vibration.

When a side ratio (a ratio of length of the long side of the crystal element 10 to thickness of the crystal element 10) of the crystal resonator becomes equal to or less than 100, an unwanted response starts to appear due to face shear vibration. In particular, in the crystal resonator 1 of the side rate of equal to or less than 50, an unwanted response due to the face shear vibration becomes large. Therefore, the present disclosure shows greater effect for use in the crystal resonator 1 of the side rate of equal to or less than 100.

Further, from the embodiment described below, it is clear that the present disclosure has an effect insofar as the β quartz crystal portion is a region outside with respect to the excitation electrodes and occupies a region of equal to or more than 75% of the whole circumference of the crystal element.

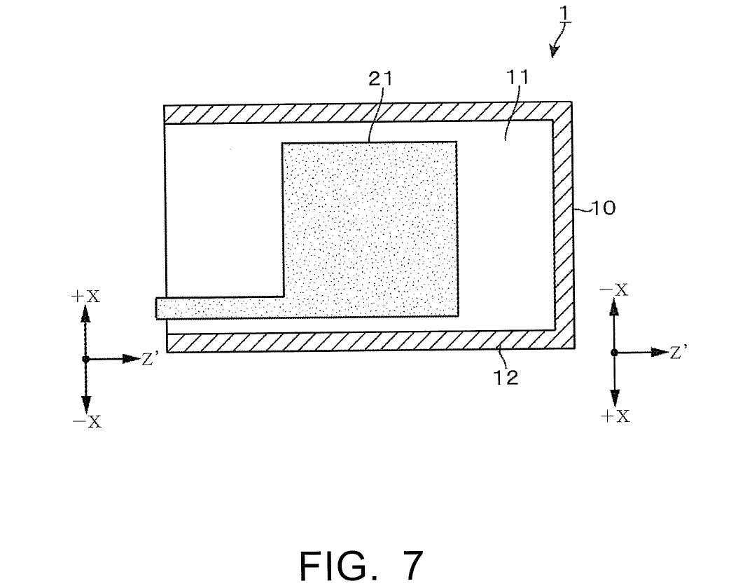

As the crystal resonator according to the embodiment of the present disclosure, as illustrated in FIG. 7, the β quartz crystal portion 12 may be formed along sides excluding one side of the rectangular crystal element 10. The face shear vibration is a vibration in the diagonal direction. Therefore, if there is a corner where the β quartz crystal portion 12 is not formed, the corner part vibrates, resulting in generation of unwanted response. If the β quartz crystal portion 12 is formed at every corner but the β quartz crystal portion 12 is not formed at opposed two sides, for example, the face shear vibration is performed back and forth of the two sides where the β quartz crystal portion 12 is not formed, rather than the diagonal direction, possibly resulting in generation of an unwanted response.

Forming the β quartz crystal portion 12 at all the remaining sides excluding one side at the crystal resonator, that is, forming the β quartz crystal portion 12 at three sides at the rectangular crystal resonator 1, forms the β quartz crystal portion 12 on all corners. This eliminates a corner that performs the face shear vibration. Since the three sides are the β quartz crystal portion, there is no possibility of generating the face shear vibration in the direction to the opposed two sides. Accordingly, the reduction of unwanted response is not limited to the case where the β quartz crystal portion 12 is formed across the whole circumference of the crystal element but also the β quartz crystal portion 12 is formed at three sides. Further, a side where the β quartz crystal portion 12 is not formed is configured as a part secured to the supporting portion, and the conductive adhesive is applied to both ends of the side where the β quartz crystal portion 12 is not formed. This secures the β quartz crystal portion 12 to the supporting portion. This configures both ends of the side where the β quartz crystal portion 12 is not formed as a fixed end. Accordingly, the side where the β quartz crystal portion 12 is not formed is also less likely to deform, further reducing generation of the unwanted response.

### WORKING EXAMPLE

The following test was carried out to validate the advantageous effects of the crystal resonator 1 according to the embodiment of the present disclosure. The crystal element 10 was formed to a rectangular shape with length of 5.0 mm and a width of 2.5 mm, and a nominal frequency was 26 MHz. The excitation electrode was made of Cr and Au and formed at a size of 2.0 mm×2.0 mm with thickness of 100 nm. The conductive adhesive is applied over the two terminal portions of the crystal resonator 1 and then the crystal resonator 1 is secured to the supporting portion. The inside of the container 6 internally housing the crystal resonator 1 is vacuumed.

In the working example, twins were formed at 0.15 mm width along four sides of the crystal element. That is, a region of 4.7 mm×2.2 mm of the crystal element performed thickness shear vibration. As a comparative example, one side opposed to the side secured to the supporting portion was configured to twins with width of 0.15 mm.

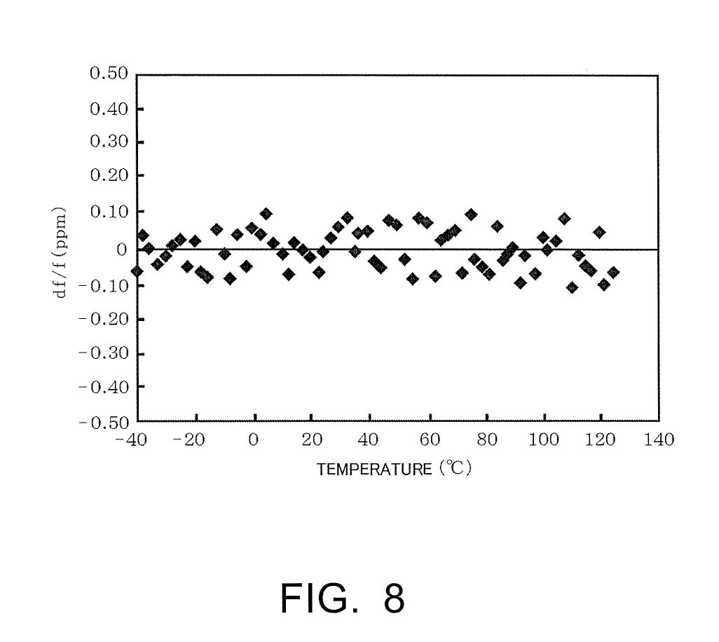

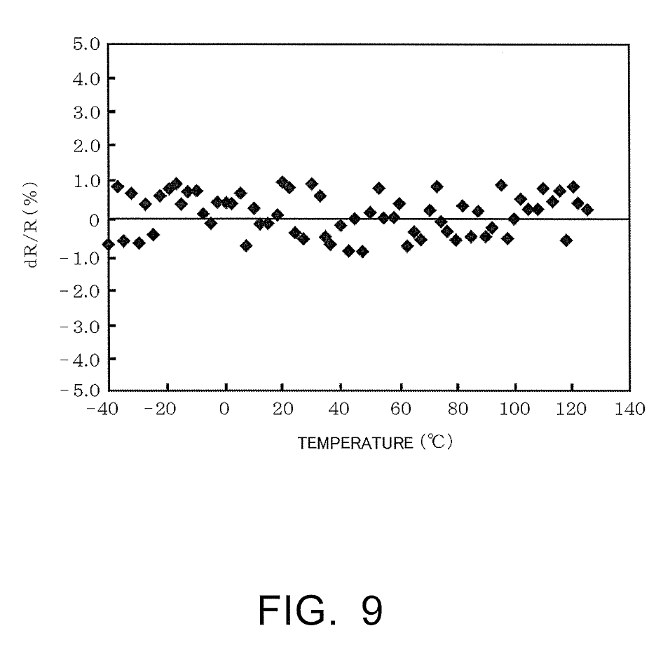

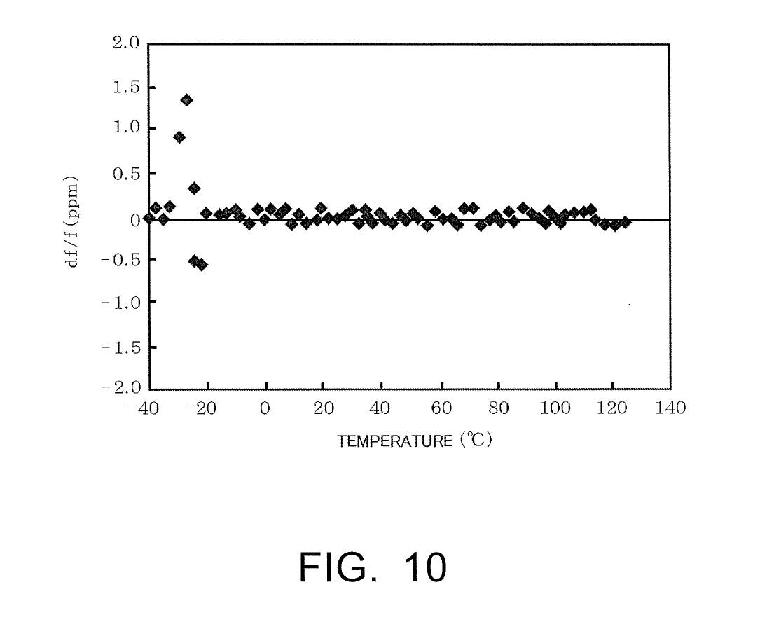

Regarding each working example and comparative example, the temperature characteristics of a resonance frequency was examined applying a π circuit technique. Regarding the working example, temperature characteristics of a motional resistance was examined applying the π circuit technique. Here, the drive current of the crystal resonator is 2 mA±10%. The resonance frequency was detected from −40° C. to 125° C. at intervals of 2.5° C. to obtain a fourth-order regression formula approximated by a detected value. The motional resistance was detected at a similar temperature. FIG. 8 and FIG. 10 are characteristic views illustrating a relationship between a respective resonance frequencies and temperatures in the working example and the comparative example. In each temperature calculated from the approximation formula, a difference between a resonance frequency and a measured value is expressed in ppm. This value is plotted for each temperature. FIG. 9 is a characteristic view illustrating a relationship between a motional resistance and a temperature in the working example. A difference between an average value and a measured value of the detected value is expressed in ppm. This value is plotted for each temperature.

With this result, in the comparative example, Frequency dips were observed at a frequency near −30° C. However, in the working example, frequency jump did not occur. It is found that Activity dips and Frequency dips can be reduced in the case where the crystal resonator of the working example of the present disclosure is used.

What is claimed is:

1. A crystal resonator, comprising:
a plate-shaped crystal element supported to a supporting portion, the crystal element being configured to vibrate at a thickness shear vibration;
excitation electrodes disposed at both surfaces of a first crystal region of the crystal element; and
a second crystal region formed at a peripheral edge portion of the crystal element in the outside of the excitation electrodes so as to occupy a region of equal to or more than 75% of a whole circumference of the crystal element, a positive/negative direction of an X-axis of a crystal in the second crystal region being reverse to a positive/negative direction of an X-axis of a crystal in the first crystal region.

2. The crystal resonator according to claim 1, wherein
the crystal element has a rectangular shape, and
the second crystal region is formed at least at a region of the peripheral edge portion along three sides of the crystal element.

3. The crystal resonator according to claim 2, wherein
the crystal element is secured to a supporting portion at positions of both ends of one side where a second crystal region is not formed.

4. The crystal resonator according to claim 1, wherein
the crystal element is cut out at an AT-cut, and
the first crystal region is an AT-cut region where a positive/negative direction of an X-axis remains in cutout of the crystal element.

5. The crystal resonator according to claim 1, wherein
the crystal element has a ratio of maximum length lengthwise of the crystal element to thickness of the crystal element value of equal to or less than 100.

6. The crystal resonator according to claim 1, wherein
the crystal element has a rectangular shape,
the second crystal region is formed in a strip shape, and
assuming that a separation distance between sides of the crystal elements opposed to one another is “d”, a width of the second crystal region is 0.1d to 0.2d.

7. The crystal resonator according to claim 1, wherein
the crystal element has a circular shape,
the second crystal region is formed in a strip shape, and
assuming that a diameter of the crystal element is “r”, a width of the second crystal region is 0.1r to 0.2r.

8. A crystal resonator package, comprising:
the crystal resonator according to claim 1 disposed in a container; and
an electrode portion disposed in the container, the electrode portion being configured to electrically connect the excitation electrode and an external conductive path.

9. An oscillator, comprising:
the crystal resonator package according to claim 8; and
an oscillator circuit connected to the electrode portion, the oscillator circuit being configured to oscillate the crystal resonator.
